(19) United States
(12) Patent Application Publication
(10) Pub. No.: US 2015/0214261 A1
(43) Pub. Date: Jul. 30, 2015

(54) MULTISPECTRAL IMAGING USING SILICON NANOWIRES

(71) Applicants: President and Fellows of Harvard College, Cambridge, MA (US); Zena Technologies, Inc., Topsfield, MA (US)

(72) Inventors: Hyunsung Park, Cambridge, MA (US); Yaping Dan, Cambridge, MA (US); Kwanyong Seo, Cambridge, MA (US); Young June Yu, Cranbury, NJ (US); Peter Duane, Waltham, MA (US); Munib Wober, Topsfield, MA (US); Kenneth B. Crozier, Cambridge, MA (US)

(73) Assignees: President and Fellows of Harvard College, Cambridge, MA (US); Zena Technologies, Inc., Topsfield, MA (US)

(21) Appl. No.: 14/421,614

(22) PCT Filed: Aug. 12, 2013
(86) PCT No.: PCT/US2013/054524

§ 371 Date: Feb. 13, 2015

Related U.S. Application Data
(60) Provisional application No. 61/756,320, filed on Jan. 24, 2013.
(60) Provisional application No. 61/682,717, filed on Aug. 13, 2012.

(51) Int. Cl. H01L 27/146; H01L 31/028; G02B 5/20

(52) U.S. Cl. CPC H01L 27/14621; G02B 5/201; G02B 5/207; H01L 27/14645; H01L 27/14685; H01L 31/028; Y10S 977/765; Y10S 977/932; B82Y 20/00

(57) ABSTRACT

An optical apparatus, including an optical filter comprising an array of nanowires oriented perpendicular to a light incidence surface of the filter, wherein the optical filter transmits light at a first wavelength that is incident on the incidence surface, wherein the first wavelength is based on a cross-sectional shape of the nanowires. The nanowires are created using a single lithography step. An imaging device and a method of fabricating the same, the device including an array of nanowires formed on a substrate, wherein at least one nanowire in the array of nanowires includes a photoelectric element to produce a photocurrent based, at least in part, on incident photons absorbed by the at least one nanowire.

### RELATED APPLICATIONS

This application claims priority under 35 U.S.C. §119(e) to U.S. application No. 61/682,717, filed Aug. 13, 2012 and U.S. application No. 61/756,320, filed Jan. 24, 2013, the entire contents of which are incorporated herein by reference.

### FEDERALLY SPONSORED RESEARCH

This invention was made pursuant to DARPA grant proposals numbers N66001-10-1-4008 and W911NF-13-2-0015, and NSF grant number ECCS-130756. The US government has certain rights in the invention.

### BACKGROUND OF INVENTION

This application relates generally to multispectral imaging. Specifically, this application relates to multispectral imaging devices using nanowires and methods of making the same.

Conventional color imaging devices, such as digital cameras, use pixelated monochromatic image sensors, such as charge-coupled devices (CCDs), in connection with three different color filters to generate color images, as illustrated schematically in FIG. 1A. The conventional imaging devices includes a lens 120, filters 130 and photodetectors 140. The three different color filters 130 typically transmit broadband portions of the visible spectrum centered on a red wavelength 136, a green wavelength 134 and a blue wavelength 132, for example, 650 nm, 532 nm and 473 nm, respectively, as illustrated in FIG. 1B. Each filter is sufficiently broadband such that the three filters cover the entire visible spectrum. Each “pixel” of the image sensor comprises three “sub-pixels,” each of which detects the amount of light transmitted through an associated one of the three colored filters. FIG. 1A illustrates a single pixel with three sub-pixels, each sub-pixel comprising a lens 120, filters 130 and photodetectors 140. The lens 120 collects incident light 110 and guides the light through filters 130. Each filter 130 transmits one band of colored light, but substantially blocks all other colored light such that photodetectors 140 detect only the light transmitted by the associated filter 130. By using an array of such pixels, a color image may be created based on the three images 150 formed from the sub-pixels associated with each color.

“Multispectral imaging” uses more than three filters with narrower bandwidths than conventional RGB imaging and can therefore extend the capabilities of the human eye. An example of multispectral imaging is shown in FIG. 1C, which illustrates N narrow bands of radiation (labeled 1-8) detected in a manner similar to that illustrated in FIG. 1A, except with a greater number of filters. The portion of the electromagnetic spectrum covered by the filters may extend into the ultraviolet and/or the infrared, thereby providing more information than is acquired with conventional visible spectrum imaging devices, such as the example shown in FIG. 1A. In the specific case illustrated in FIG. 1C, N=8 and eight images, one associated with each narrowband filter, is created based on the photocurrent detected from an array of photodetectors under the filters. Multispectral has many applications in both military and civilian applications, such as remote sensing, vegetation mapping, non-invasive biological imaging, face recognition and food quality control. Conventional multispectral imaging devices include devices that use motorized filter wheels, multiple image sensors, and/or multilayer dielectric interference filters.

### SUMMARY OF INVENTION

Accordingly, some embodiments are directed to an optical apparatus, comprising an optical filter comprising an array of nanowires oriented perpendicular to a light incidence surface of the filter, wherein the optical filter transmits light at a first wavelength that is incident on the incidence surface, wherein the first wavelength is based on a cross-sectional area of the nanowires.

Some embodiments are directed to a method of manufacturing an optical filter. The method includes forming a plurality of nanowires on a substrate, wherein the nanowires are arranged perpendicular to a surface of the substrate; embedding the plurality of nanowires in a polymer layer; and separating the polymer layer and plurality of nanowires from the substrate. forming a plurality of nanowires may include: forming a plurality of metallic masks on the substrate; and etching a portion of the substrate not covered with the plurality of metallic masks.

Some embodiments are directed to an imaging device including: an array of nanowires formed on a substrate, wherein at least one nanowire in the array of nanowires includes a photoelectric element to produce a photocurrent based, at least in part, on incident photons absorbed by the at least one nanowire. The at least one photoelectric element may be a p-n junction or a p-i-n junction. The at least two nanowires in the array may have different radii to selectively absorb incident photons at a particular wavelength.

Some embodiments are directed to a method of fabricating an imaging device. The method may include: forming an epitaxial structure comprising an n-type semiconductor layer and a p-type semiconductor layer on a substrate to create a p-n junction between the n-type layer and the p-type layer; etching the epitaxial structure to form an array of nanowires on the substrate, wherein each nanowire includes a p-n junction as formed in the epitaxial structure; and forming an electrical contact on at least one nanowire in the array of nanowires.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1A a schematic illustration of a portion of a conventional color imaging device;

FIG. 1B illustrates the three broadband filters of conventional color imaging;

FIG. 1C illustrates the multiple narrowband filters of multispectral color imaging;

FIG. 2A is a schematic illustration of a cross section of a filter using nanowires according to some embodiments;

FIG. 2B is a schematic illustration of a top view of a filter using nanowires according to some embodiments;

FIG. 2C is a scanning electron microscope image of etched nanowires according to some embodiments;

FIG. 3 illustrates an experimental measurement of the filter transmission as a function of wavelength for filters comprising nanowires of varying values of radius;

FIG. 4A illustrates a nanowire with an elliptical cross-section according to some embodiments;

FIG. 4B illustrates a polarization dependent spectral response of an elliptical nanowire according to some embodiments;

FIG. 5A shows a schematic diagram of an imaging device with a plurality of sub-pixels according to some embodiments;

FIG. 5B shows a schematic diagram of an imaging device with a plurality of sub-pixels according to some embodiments;

FIG. 6A-C illustrate a method of manufacturing a nanowire filter according to some embodiments;

FIG. 7 is a flow chart of a method of manufacturing a nanowire filter according to some embodiments;

FIG. 8 is a flow chart of a method of forming nanowires on a substrate according to some embodiments;

FIG. 9 is a schematic diagram of a silicon nanowire photodetector according to some embodiments;

FIG. 10A-C illustrate a method of forming nanowire photodetectors according to some embodiments;

FIG. 11 is a flow chart of a method of forming nanowire photodetectors according to some embodiments; and

FIG. 12 illustrates an imaging device comprising both nanowire photodetectors and conventional photodetectors according to some embodiments.

### DETAILED DESCRIPTION OF INVENTION

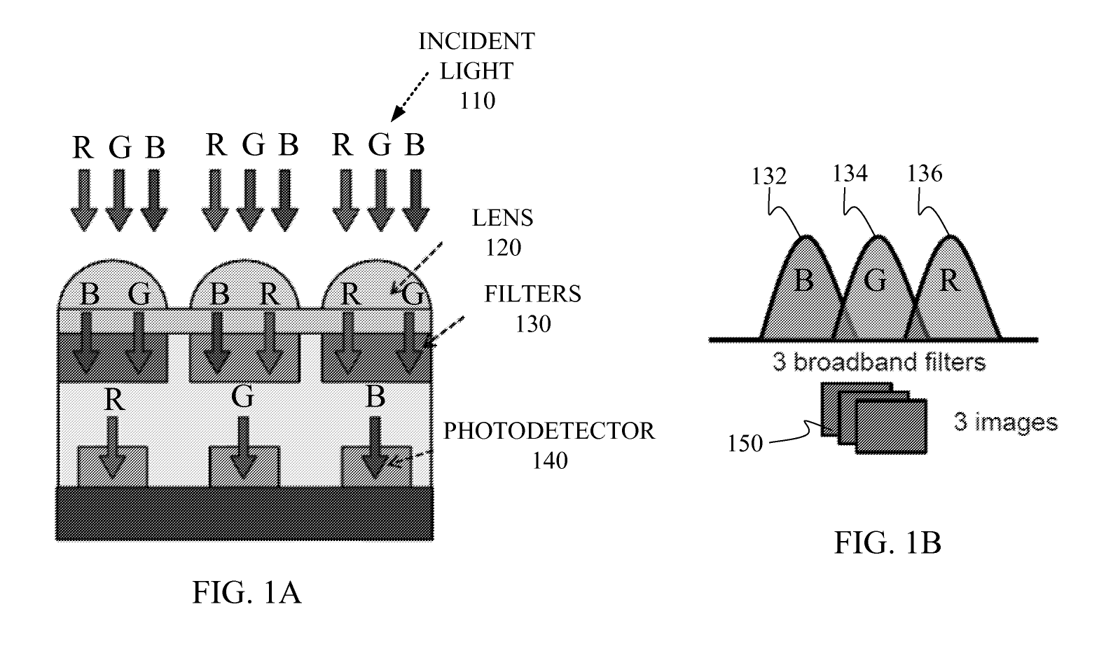

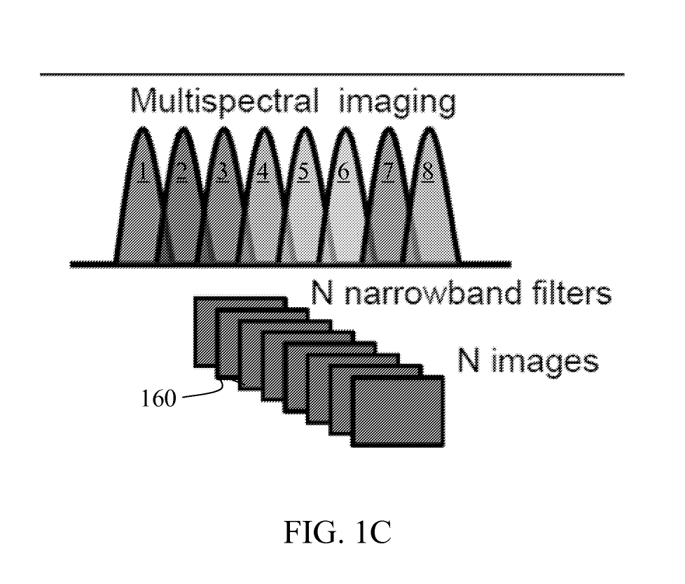

The inventors have recognized and appreciated that conventional multispectral imaging devices are expensive and/or bulky and that more efficient multispectral imaging devices that may be manufactured more simply and efficiently are needed. Accordingly, some embodiments are directed to a filter comprising silicon nanowires that may be created with a single lithographic step. The nanowire filter uses the wavelength-dependent absorption and scattering of light by nanowires to filter light at particular wavelengths. The absorbed and scattered light at the particular wavelength are prevented from transmitting through the filter. The wavelength of light absorbed by a particular nanowire is proportional to the radius of the nanowire—the larger the radius, the larger the absorbed wavelength. Thus, the nanowire filters are subtractive color filters, which block light within a narrow wavelength range, as opposed to the example shown in FIG. 1C, which illustrates narrowband filters that transmit only a narrow wavelength range. Despite being subtractive color filters, nanowire filters may be mounted to an image sensor, such as a CCD array, to form multispectral images.

The inventors have also recognized and appreciated that a benefit of creating a nanowire filter that filters light at particular wavelengths based on the radius of the nanowires is that the filter may be created with only a single photolithography step. Even in embodiments where different portions of the filter include of nanowires with different radii, only a single photolithography step is required. This is advantageous compared to, for example, a multilayer dielectric interference filter, which requires multiple precisely made layers of dielectric material. The process of creating multilayer dielectric interference filters with different portions of the filter transmitting different wavelengths is even more complicated and may require multiple lithography steps.

The inventors have also recognized and appreciated that using a filter prior to detection by an image sensor has poor performance in low-light level environments because only a small portion of the incident light is detected, while the majority of the light is absorbed or reflected by the filter. Accordingly, some embodiments are directed to a nanowire device where each nanowire has a p-n junction and selectively detects light at a particular wavelength. In this way, each nanowire acts as a wavelength selective photodetector. Light at a wavelength other than the selected wavelength transmits through the nanowire array. The inventors have recognized and appreciated that rather than letting the transmitted light go to waste, a conventional photodetector may be placed under the nanowire structure to detect the transmitted light. In this way, very little light is wasted as most of the incident light is detected by either the nanowire photodetectors or the conventional photodetectors. Because the incident light is used more efficiently by such imaging devices, operation in low light environments is superior to conventional digital imaging devices.

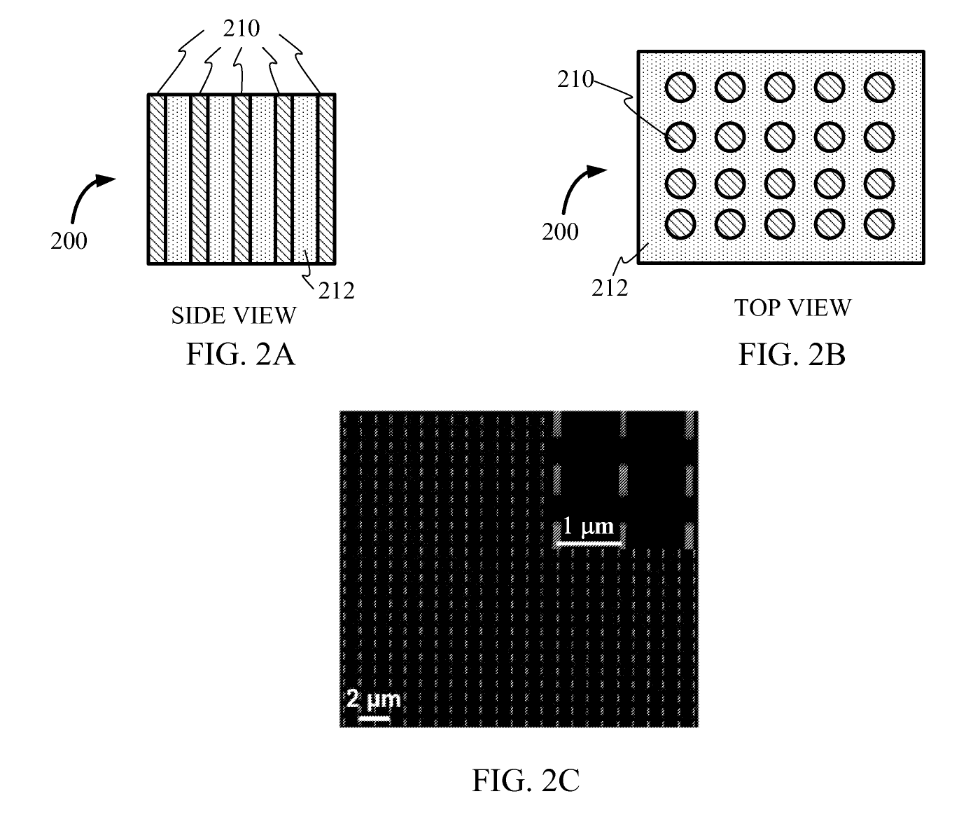

Some embodiments are directed to an optical apparatus comprising an array of nanowires embedded in a polymer. By way of example and not limitation, the optical apparatus may be an optical filter, an imaging device that includes an optical filter, or a display device that includes an optical filter. FIG. 2A illustrates a side-view cross-section of an optical filter 200 comprising nanowires 210 embedded in a polymer 212. The nanowires 210 may be made from any suitable material. It may be preferable to use a material with a relatively high refractive index in the vicinity of the wavelength of light being filtered. For example, a refractive index greater than 2.0 at the peak absorption wavelength of the nanowire is preferable. More preferable is a refractive index greater than 3.0 at the peak absorption wavelength of the nanowire. In some embodiments, the nanowires 210 may be made from a semiconductor material. By way of example and not limitation, the semiconductor material may be silicon (Si), germanium (Ge) or indium gallium arsenide (InGaAs). The semiconductor material may be selected based on the desired filtering wavelength. For example, silicon may be selected for use with the visible light (ranging from approximately 380 nm to 750 nm) and near infrared (NIR) (ranging from approximately 750 nm to 1.4 μm), whereas germanium may be selected for use in the shortwave infrared (SWIR) (ranging from approximately 1.4 μm to 3.0 μm).

The nanowires 210 may be formed in any shape. The nanowires 210 extend longitudinally in a first direction. The nanowires may be any suitable length. By way of example and not limitation, the nanowires may be 1.0 to 2.0 μm long. The cross-sectional area of the nanowires perpendicular to the first direction determines the spectral response of the nanowires. FIG. 2B illustrates a top view of an array of circular nanowires 210 embedded in a polymer 212. The nanowires in FIG. 2B have cross-sections shaped like circles. Embodiments are not so limited. For example, some embodiments may include elliptical, square, rectangular or any other cross-sectional shape. Nanowires with circular cross-sections respond identically to light of any polarization. The filtered wavelength for circular nanowires is determined by the radius of the nanowire. Nanowires with elliptical cross-sections, on the other hand, filter different wavelengths depending on the polarization of the light. Light with polarization oriented along the minor axis of the ellipse will be subject to peak absorption at a lower wavelength than light with polarization oriented along the major axis of the ellipse.

Any suitable number of nanowires may be included in an array. Also, any suitable spacing between nanowires in an array may be used. FIGS. 2A and 2B illustrate nanowires with identical spacing of 1.0 μm. FIG. 2C is a scanning electron microscope image of an array of silicon nanowires on a silicon substrate with a spacing of 1.0 μm. However, embodiments are not so limited. In some embodiments, 500 nm separation between nanowires may be used. FIG. 2B illustrates an identical spacing in both a first direction and a second direction (represented vertically and horizontally in FIG. 2B). However, the spacing between nanowires need not be uniform. The spacing of the nanowires may differ depending on the location within the array. For example, a first sub-array of the array of nanowires may have a first spacing and a second sub-array of the array of nanowires may have a second spacing. Any suitable number of nanowires and sub-arrays may be used. Embodiments are not limited to any particular spacing or number of nanowires in the array.

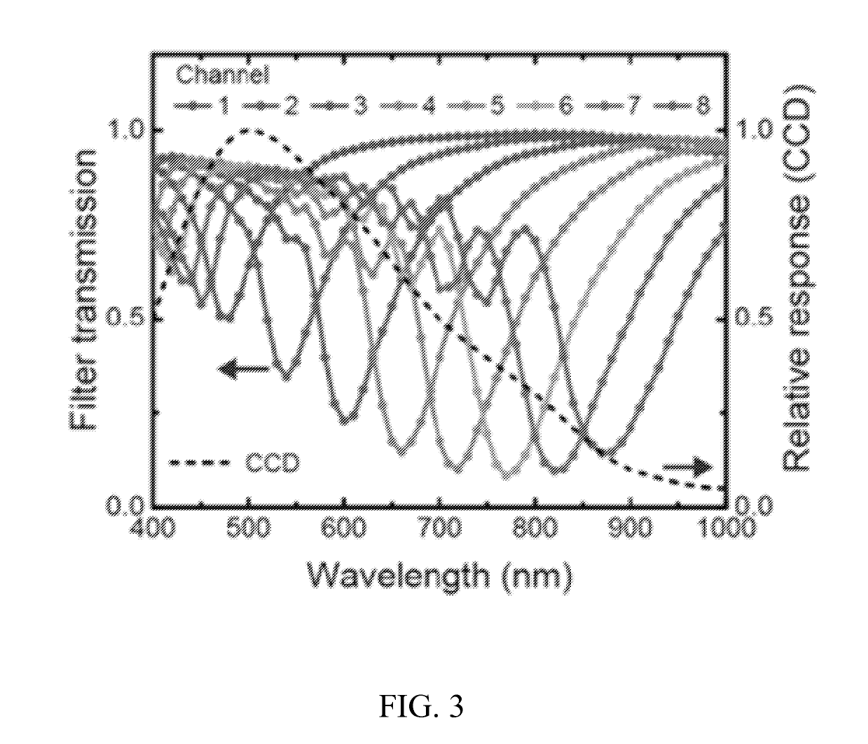

The nanowires 210 may have any suitably sized cross-section. For example, circular silicon nanowires that absorb light in the visible and NIR spectrum may range from 45-80 nm in radius. The wavelength of light absorbed by the nanowires is proportional to the radius of the circular cross-section. FIG. 3 shows an experimental measurement of filter transmission with respect to the wavelength of light incident on the filter for circular silicon nanowires of various radii. The measurement illustrated in FIG. 3 shows channels 1-8, which correspond to radii of 45 nm, 50 nm, 55 nm, 60 nm, 65 nm, 70 nm, 75 nm, and 80 nm, respectively. By way of example, circular silicon nanowires with a radius of 45 nm have a peak absorption wavelength of approximately 470 nm and circular silicon nanowires with a radius of 80 nm have a peak absorption wavelength of approximately 870 nm.

Embodiments of optical filter 200 may use any suitable polymer 212. In embodiments where light transmitted by the filter is detected by a photodetector, it is preferable that the polymer 212 be substantially transparent for the detected spectral range. In some embodiments, the polymer may be polydimethylsiloxane (PDMS).

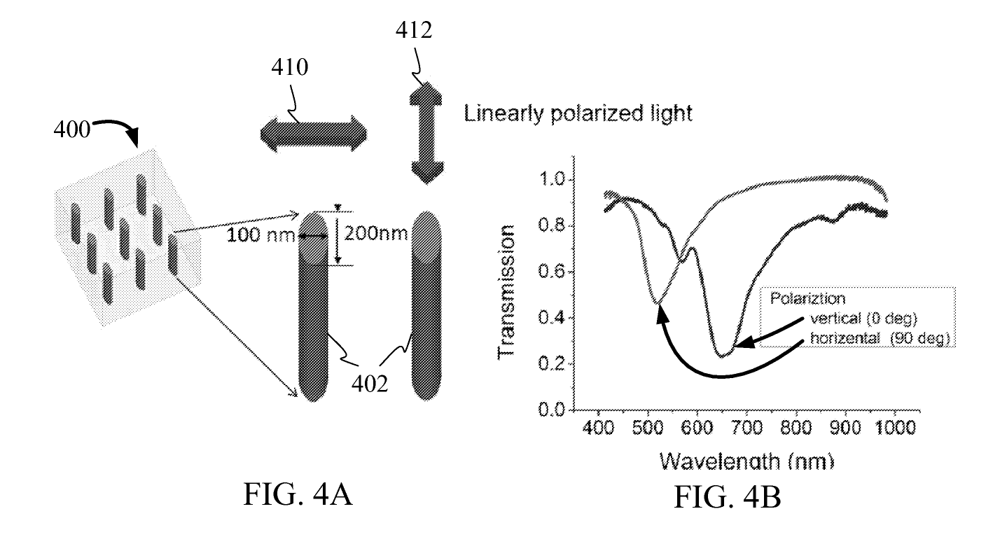

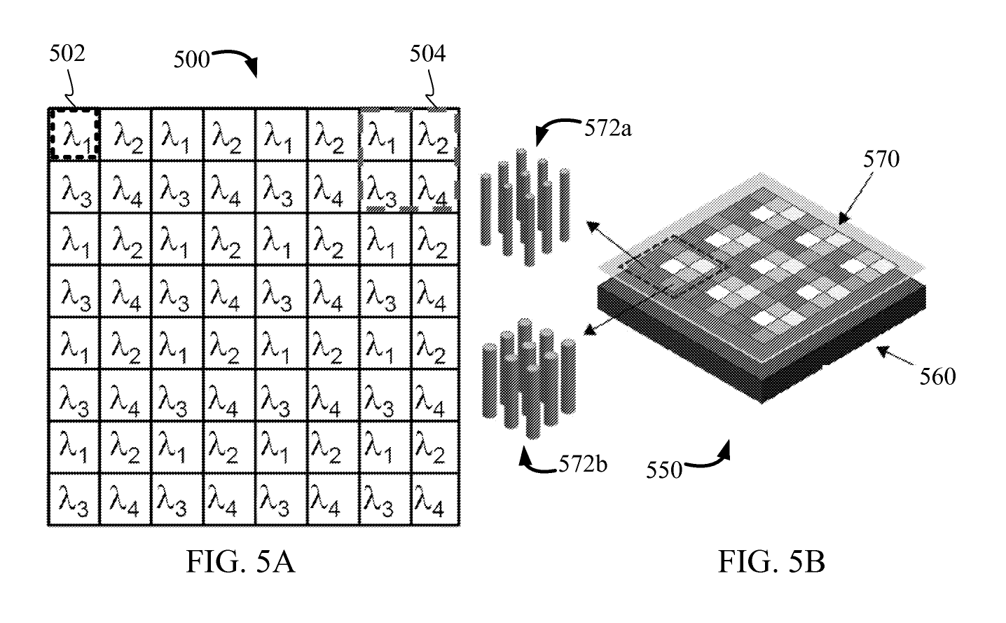

As mentioned above, some embodiments may use elliptical nanowires. In such embodiments, the spectral response of the nanowires is dependent on the polarization of the incident light. FIG. 4A illustrates a filter 400 comprising elliptical nanowires 402. The cross-section of each of the nanowires is elliptical with a minor axis that is 100 nm and a major axis that is 200 nm. Light incident on the filter 400 may be horizontally polarized 410 and aligned with the minor axis of the ellipse or vertically polarized 412 and aligned with the major axis of the ellipse. FIG. 4B illustrates the spectral response of the filter by showing the transmission of the filter as a function of wavelength for both horizontally and vertically polarized light. The absorption peak for horizontal light is at approximately 510 nm, whereas the absorption peak of vertically polarized light is at approximately 650 nm. It should be appreciated that any suitable lengths of major and minor axes may be used.

FIGS. 5A and 5B illustrate how a nanowire filter may be used in connection with a monochromatic image sensor to create a compact, efficient, multispectral imaging device. FIG. 5A illustrates an array of sub-pixels of an imaging device 500 according to some embodiments. The image sensor is segmented into an array of sub-pixels (sub-pixel 502 is shown with a dashed line to illustrate the definition of a sub-pixel herein). A unit cell of four sub-pixels defines a pixel (pixel 504 is shown with a dashed line to illustrate the definition of a pixel herein). Each sub-pixel of a pixel detects a different range of wavelengths, illustrated as λ1, λ2, λ3 and λ4. The unit cell is repeated in a 4×4 array of pixels comprising a total of 64 sub-pixels, 16 sub-pixels detecting each of the four wavelength ranges. The embodiment of FIG. 5A is by way of example and not meant to be limiting. Any number of pixels and sub-pixels may be used in an image sensor array. The number may be selected based on the desired applications of the imaging device and the number of spectral ranges being detected.

FIG. 5B illustrates a 3×3 pixel image imaging device 550 where each pixel comprises 9 sub-pixels in a 3×3 array. The imaging device 550 includes a monochromatic image sensor 560 and a filter 570. The filter comprises nanowires embedded in PDMS. Each of the sub-pixels comprises an array of nanowires 572, wherein each of the nanowires of a particular sub-pixel have the same radius and, therefore, absorb the same wavelength light. Each sub-pixel within a pixel absorbs a different wavelength and therefore has a different size radius. By way of example, FIG. 5B illustrates an array of nanowires 572a of a first sub-pixel having a first radius and an array of nanowires 572b of a second sub-pixel having a second radius larger than the first radius.

The filter 570 may be affixed to the monochromatic image sensor 560 in any suitable way. In some embodiments, the filter 570 is applied directly to the detection surface of the monochromatic image sensor 560. In other embodiments, there may be one or more optical elements between the filter 570 and the monochromatic image sensor 560.

As described above, the nanowires of the filter 570 may be created with a single lithography step. The array of nanowires may be split into a plurality of sub-arrays, each sub-array associated with a sub-pixel. Any number of nanowires may be included in a sub-array associated with a sub-pixel. For example, in some embodiments, a sub-pixel is 24 μm×24 μm and the sub-pixel contains a sub-array of 24×24 nanowires (576 nanowires per sub-array). The array associated with the filter as a whole may consist of any suitable number of sub-arrays. For example, a unit cell representing a pixel may comprises any number of sub-pixels, each sub-pixel filtering a different set of wavelengths. Thus, each unit cell (pixel) of the 3×3 pixel imaging device 550 illustrated in FIG. 5B may include a 3×3 array of sub-pixels, each with a different filter so as to filter the light in nine different ways.

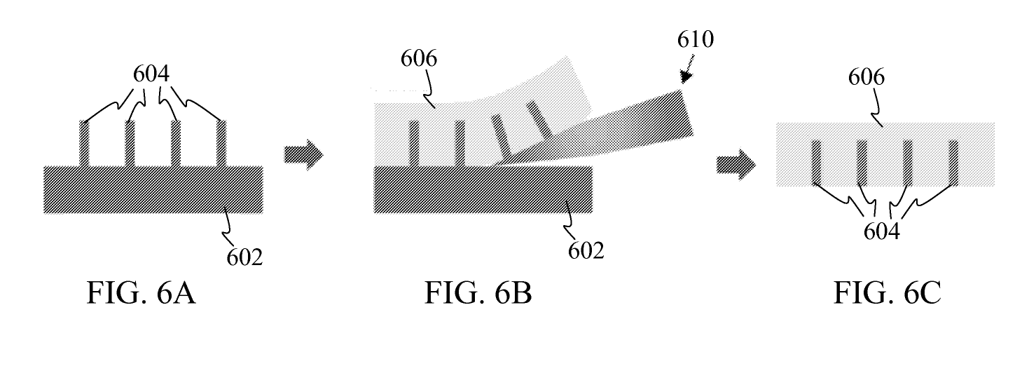

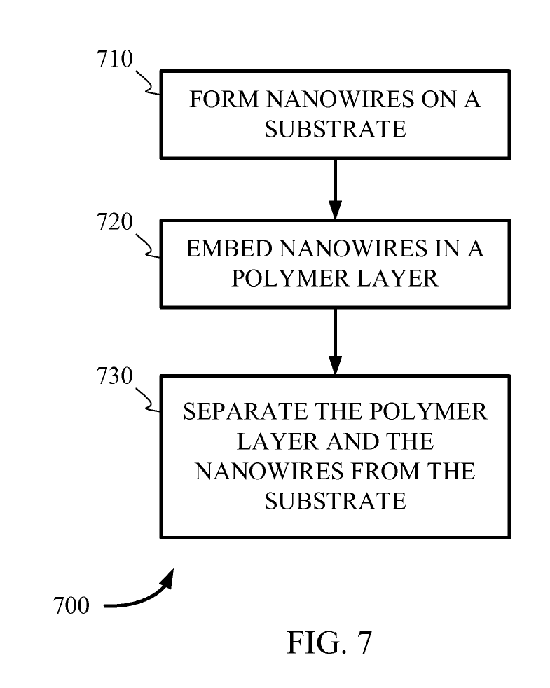

FIG. 6A-C illustrates a method of manufacturing a nanowire filter according to some embodiments and is described in connection with FIG. 7, which is a flowchart of the method 700 of manufacturing a nanowire filter according to some embodiments.

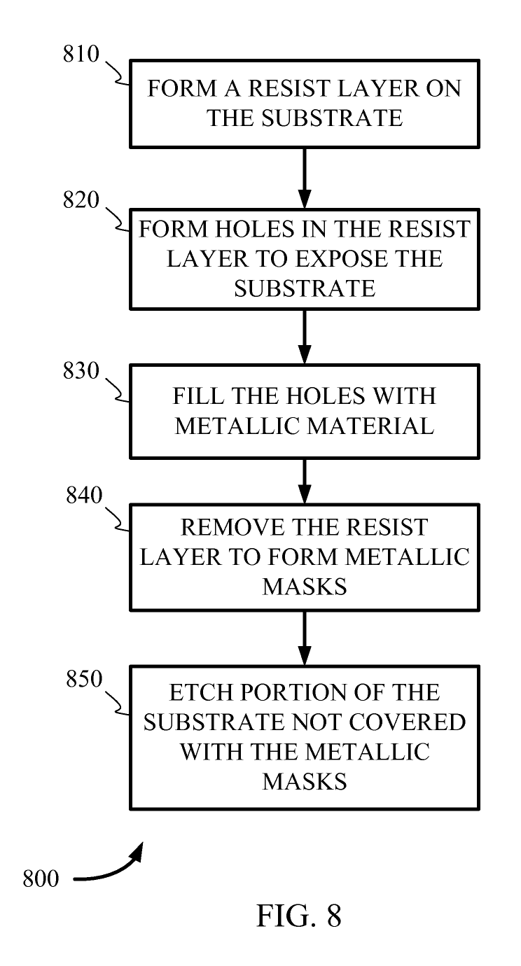

At act 710, a plurality of nanowires 604 are formed on a first surface of a substrate 602. The nanowires 604 are arranged “vertically” such that the longitudinal axis of the nanowires is perpendicular to the first surface of the substrate 602. As described above, the nanowires may be of any suitable length and shape. The nanowires 604 may be formed in an array comprising a plurality of sub-arrays, wherein each sub-array comprises nanowires of the same radius, but nanowires in other sub-arrays have different radii. The nanowires 604 may have any suitable cross-sectional shape, such as circular or elliptical. In some embodiments, the nanowires 604 are formed from the substrate material itself, such that the substrate 602 is made from the same material as the nanowires 604. In other embodiments, the nanowires 604 may be formed from a different material than the substrate 602. Details of one exemplary method of forming nanowires on a substrate are described below in connection with FIG. 8.

At act 720, the plurality of nanowires are embedded in a polymer layer 606. Any suitable polymer may be used, such as PDMS. The nanowires may be embedded in the polymer in any suitable way. For example, the PDMS may be spin coated onto the wafer with the vertical nanowires. The PDMS layer 606 may then be cured and cooled.

At act 730, the polymer layer 606 with the embedded nanowires 604 is separated from the substrate 602. This may be done in any suitable way. For example, the polymer layer 606 may be cut away from the substrate 602 using a cutting device, such as a razor blade 610. Separating the polymer 606 from the substrate 602 leaves a filter comprising a polymer 606 where both surfaces of the filter are free from other layers (e.g., the substrate layer was cut away). This, either the top surface or the bottom surface may be used as a light incidence surface and the other surface would be used as a light output surface.

As described above, the nanowires 604 may be formed on substrate 602 in any suitable way. FIG. 8 is a flow chart of a method 800 for forming the nanowires 604 on the substrate 602. At act 810, a resist layer is formed on a first surface of the substrate. Any suitable resist may be used, such as polymethyl methacrylate (PMMA).

At act 820, a plurality of holes in the desired size and shape of the nanowires are formed in desired locations in the resist layer. The holes may be formed in any suitable way. For example, electron beam lithography may be used to expose the desired regions of the resist such that when developed, the exposed regions of the resist layer may be rinsed away. The holes left in the resist layer expose the surface of the underlying substrate.

At act 830, the plurality of holes are at least partially filled with a hard mask material. Any suitable hard mask material may be used. Preferably the hard mask material etches at a lower rate than the rate at which the material of the substrate etches. For example, a metal material may be used as a hard mask material. In some embodiments, aluminum is used to fill the holes. The holes may be filled with aluminum in any suitable way. For example, aluminum may be evaporated using a thermal evaporator.

At act 840, the resist layer is removed so as to expose the surface of the substrate at all location other than the locations of the substrate covered with the hard mask (e.g., aluminum). The resist layer may be removed in any suitable way, such as immersing the entire wafer in acetone. Embodiments are not limited to using acetone. Any liquid that dissolves the resist material may be used.

At act 850, the portions of the substrate not covered by the hard mask are etched. Any suitable etching process may be used. In some embodiments, reaction ion etching is used using, for example, SF₆ and/or C₄F₈ as an etchant. After etching, the nanowires are formed and are integrally attached to the substrate as they are formed from the original substrate material.

In some embodiments, a photoelectric element, such as a p-n junction or a p-i-n junction may be formed within a semiconductor nanowire. When such a photoelectric element is present, the nanowire acts as a photodetector with a spectral response controlled by the characteristics of the cross-sectional area of the nanowire, such as the radius.

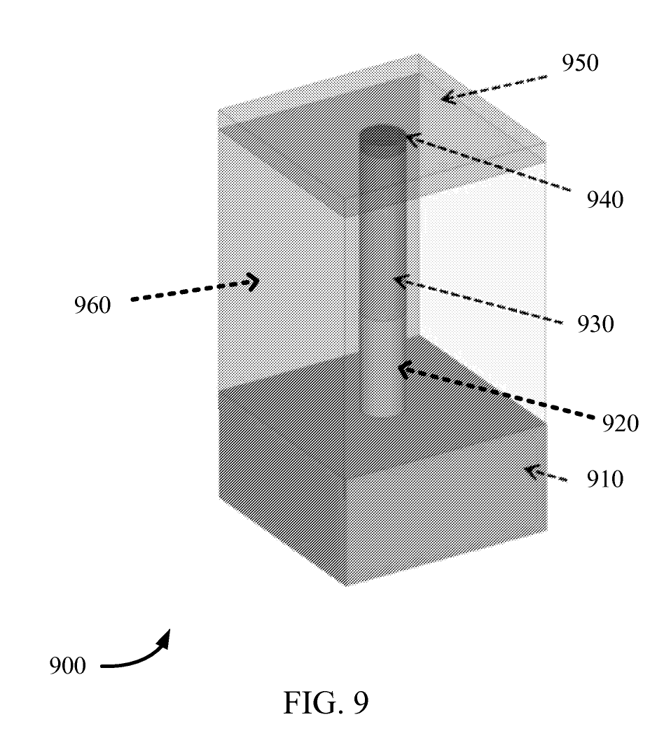

FIG. 9 illustrates an exemplary embodiment of a single nanowire photodetector 900 with a p-i-n junction. The nanowire 900 may be formed from any semiconductor material. By way of example and not limitation, silicon or germanium may be used. The nanowire 900 comprises a substrate 910 of a first conductivity type, a first nanowire region 920 of the first conductivity type, an second intrinsic nanowire region 920, a third nanowire region 940 of a second conductivity type, a transparent conductor 950 and a polymer layer 960 surrounding the nanowire. By way of example, the first conductivity type may be n-type and the second conductivity type may be p-type. However, embodiments are not so limited. For the purposes of the following discussion, the substrate will be an n-type semiconductor (n⁺).

In FIG. 9, the substrate 910 and the first nanowire region 920 are n-type semiconductors with the same doping characteristics. The intrinsic region 930 is also n-type, but with a lower concentration of donors (n⁻). The third nanowire region 940 is a p-type semiconductor (p⁺). This structure acts as a photodiode detector. The light incident upon the nanowire may be absorbed, as determined by the characteristics of the nanowires cross-section, and when the light is absorbed, a photocurrent is generated. In this way, the quantity of light at the wavelength absorbed by the nanowire may be quantitatively measured.

The regions of the nanowire may be any suitable size. By way of example and not limitation, the total length of the nanowire may be 2.0-3.0 μm and the spacing between nanowires may be 1.0 μm. The first nanowire region 920 is 600 nm long, the second intrinsic nanowire region 920 is 1400 nm long, and the third p-type nanowire region 940 is 100 nm long. The radii of the nanowires vary from 80-140 nm based on the wavelength of light that each nanowire is designed to absorb.

The nanowire may be embedded in a polymer 960, such as poly(methyl methacrylate) (PMMA), which acts as a spacer. Embodiments are not limited to PMMA, as any polymer may be used. A transparent conductor 950 is placed on top of the polymer layer 960 and over the p-type third nanowire region 940 to form an electrical contact for the nanowire photodetector 900. By way of example and not limitation, the transparent conductor 950 may be formed from indium tin oxide (ITO).

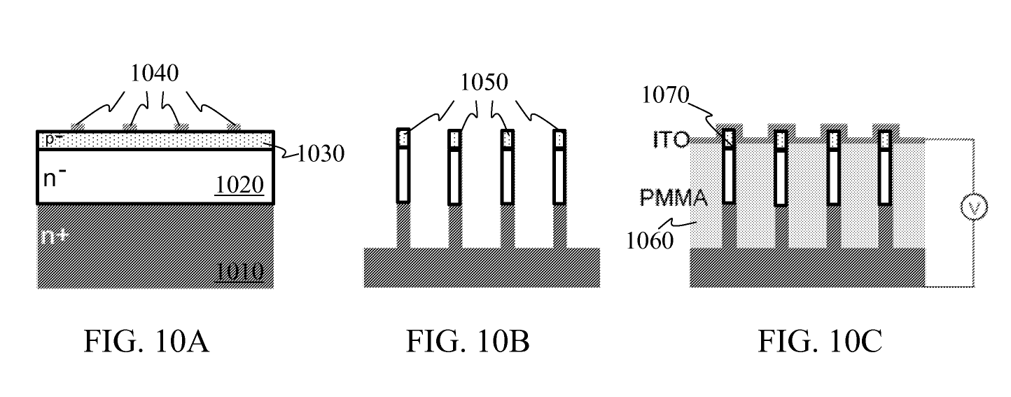

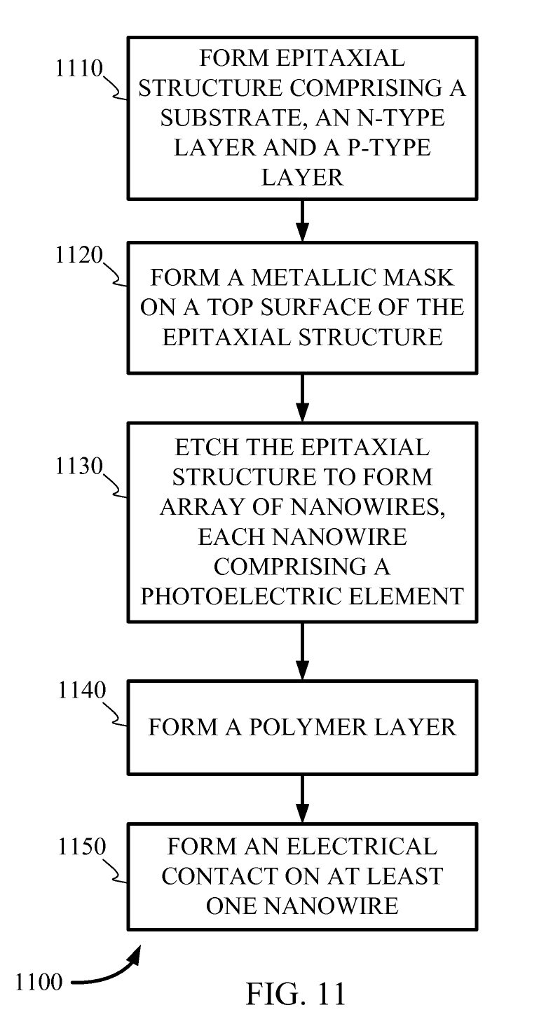

The nanowire photodetector 900 structure of FIG. 9 may be formed in any suitable way. FIG. 10A-C illustrates one possible method of forming the nanowire photodetector 900 and is described in connection with FIG. 11, which is a flow chart describing the method of forming the nanowire photodetector 900.

At act 1110, an epitaxial structure comprising a substrate, an n-type layer and a p-type layer is formed. This may be achieved in any suitable way. For example, a silicon epitaxial wafer, which includes an n-type substrate 1010 and an n⁻ silicon epitaxial layer 1020, may be used as a starting point. The n⁻ silicon epitaxial layer may be any suitable thickness. By way of example and not limitation, it may initially be 1.5 μm thick. The p-type layer 1030 may be formed by doping the top portion of the n⁻ silicon epitaxial layer to p⁺ using boron diffusion. This doping reduces the overall thickness of the n⁻ silicon epitaxial layer and forms the basic structure of the p-i-n junction.

At act 1120, metallic masks 1040 are added to the top surface of the p-type layer 1030. The metallic masks may be formed with any desired spacing, and in any desired size or shape. The metallic masks may also be formed in any suitable way. For example, the technique used in the above description of the formation of the nanowire filter may be performed to create the metallic masks 1040. At act 1130, the portions of the epitaxial structure not covered by the metallic masks 1040 is etched away to create the nanowires 1050 comprising p-i-n junctions. This may be done in any suitable way, such as reactive ion etching. However, any dry etching technique may be used.

At act 1140, a polymer layer 1060 is formed such that the nanowires 1050 are embedded in the polymer layer. Any suitable polymer may be used. In the example illustrated in FIG. 10C, PMMA is used. The PMMA layer 1060 may be created by spin casting the PMMA onto the etched wafer and curing the wafer. At act 1150, an electrical contact 1070 is formed on at least a portion of the nanowires 1050 created. This may be done in any suitable way. In some embodiments, indium tin oxide is sputtered onto the device to a thickness of 40 nm. Any suitable conductive material may be used to form the electrical contact 1070. Preferably, the material is transparent in the range of wavelengths being detected.

The nanowire photodetectors described above may be created in arrays where one nanowire photodetector detects a first wavelength and a second nanowire photodetector detects a second wavelength different from the first wavelength. Moreover, the light incident upon an imaging device comprising nanowire photodetectors may be efficiently detected by including the array of nanowire photodetectors above an array of conventional photodetectors, such as a CCD array. In this way, almost all of the light incident on the imaging device is detected.

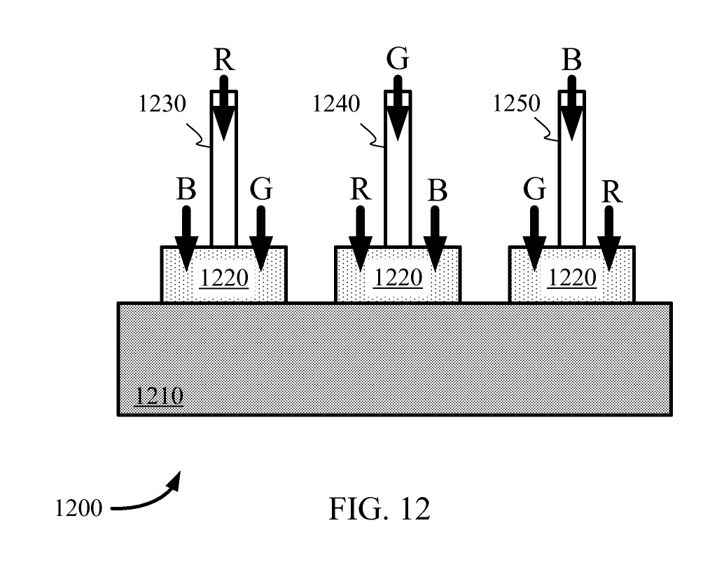

FIG. 12 illustrates an exemplary imaging device 1200 with nanowire photodetectors 1230, 1240 and 1250 above conventional photodetectors 1220. Each of the nanowire photodetectors has a different radius such that each nanowire photodetector detects a different wavelength. By way of example, only three different nanowire photodetectors are shown and for simplicity the nanowire photodetectors 1230, 1240 and 1250 are shown absorbing red, green and blue light (represented by arrows), respectively. It should be understood that any number of different nanowire photodetectors may be used and they need not be limited to detecting red, green and blue light. Light at any suitable wavelength may be detected.

Focusing on the nanowire photodetector 1230, which detects red light, it is shown that light of other wavelengths transmits past the nanowire photodetector 1230. Thus, the photodetector 1220 placed under the nanowire photodetector 1230, on the opposite side of the nanowire photodetector 1230 from the side on which the light is incident, detects the transmitted light. The conventional photodetector 1220 has a much broader spectral response than the nanowire photodetector 1230, so it is able to detect the light of other wavelengths. This description applies to the other nanowire photodetectors 1240 and 1250, except nanowire photodetectors 1240 and 1250 detect green and blue light, respectively.

As with the nanowire filter described above, the nanowire photodetectors may be arranged in sub-arrays associated with sub-pixels that all detect light of the same wavelength. In this way, a multispectral imaging device may be created that utilizes a higher percentage of the incident light than conventional imaging devices.

Embodiments may be used in a variety of applications. Filters based on nanowires may be used in any application where filters are typically used. For example, nanowire filters may be used in display devices, projector devices, and imaging devices. Nanowire photodetectors may be used in any imaging application. Imaging applications may include digital cameras that operate in the UV, visible, NIR and/or IR wavelengths. Digital cameras applications include both still and video cameras.

Having thus described several aspects of at least one embodiment, it is to be appreciated that various alterations, modifications, and improvements will readily occur to those skilled in the art. For example, the nanowire filter described above may be used in any suitable application, such as an image display device. Also, nanowires with varying radius may be used within a single sub-array to tune the spectral response of a filter. Moreover, the applications described above may be applied to other area of the electromagnetic spectrum outside of the visible and infrared wavelengths. For example, nanowire filters and photodetectors may be created for use in the ultraviolet and microwave radiation.

Moreover, any aspect of a particular embodiment described above may be combined with one or more aspects of any other embodiment described above. For example, nanowire filters without photodetectors may be used in conjunction with nanowire filters.

Such alterations, modifications, and improvements are intended to be part of this disclosure, and are intended to be within the spirit and scope of the invention. Accordingly, the foregoing description and drawings are by way of example only.

This invention is not limited in its application to the details of construction and the arrangement of components set forth in the foregoing description or illustrated in the drawings. The invention is capable of other embodiments and of being practiced or of being carried out in various ways. Also, the phraseology and terminology used herein is for the purpose of description and should not be regarded as limiting. The use of “including,” “comprising,” “having,” “containing”, “involving”, and variations thereof, is meant to encompass the items listed thereafter and additional items.

The invention may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” and “third,” etc. in the claims and/or the specification does not by itself connote any priority, precedence, or order of one claim element over another or the temporal order in which acts of a method are performed, but are used merely as labels to distinguish one claim element having a certain name from another element having a same or similar name to distinguish the claim elements.

What is claimed is:

1. An optical apparatus, comprising:
an optical filter comprising an array of nanowires oriented substantially perpendicular to a light incidence surface of the filter, wherein the optical filter transmits light at a first wavelength that is incident on the incidence surface, and wherein the first wavelength is based on a cross-sectional shape of the nanowires.

2. The optical apparatus of claim 1, wherein the array of nanowires is embedded in a polymer.

3. The optical apparatus of claim 1, wherein the polymer is polydimethylsiloxane (PDMS).

4. The optical apparatus of claim 1, wherein each of the nanowires has a substantially circular cross-sectional shape and the first wavelength is based on the radii of the nanowires.

5. The optical apparatus of claim 1, wherein each of the nanowires has a substantially elliptical cross-sectional shape and each nanowire transmits light at the first wavelength when the light has a first polarization and transmits light at a second wavelength when the light has a second polarization.

6. The optical apparatus of claim 1, wherein the array of nanowires comprises a plurality of sub-arrays, each sub-array comprising a plurality of nanowires, each of the plurality of nanowires within each sub-array having a same cross-sectional shape.

7. The optical apparatus of claim 1, further comprising:
an array of photodetectors configured to detect light transmitted by the optical filter.

8. The optical apparatus of claim 7, wherein:
the array of nanowires comprises a plurality of sub-arrays, each sub-array comprising a plurality of nanowires; and
each photodetector of the array of photodetectors is configured to receive light transmitted by a single sub-array of nanowires.

9. The optical apparatus of claim 1, wherein the nanowires comprise a semiconductor material.

10. The optical apparatus of claim 9, wherein the semiconductor material is silicon or germanium.

11. A method of manufacturing an optical filter, comprising acts of:
forming a plurality of nanowires on a substrate, wherein the nanowires are arranged substantially perpendicular to a surface of the substrate;
embedding the plurality of nanowires in a polymer layer; and
separating the polymer layer and plurality of nanowires from the substrate.

12. The method of claim 11, wherein the act of forming a plurality of nanowires comprises acts of:
forming a plurality of metallic masks on the substrate; and
etching a portion of the substrate not covered with the plurality of metallic masks.

13. The method of claim 12, wherein the act of forming a plurality of metallic masks on the substrate comprises acts of:
forming a resist layer on the substrate;
forming a plurality of holes in the resist layer at a plurality of locations to expose the substrate;
filling, at least in partially, the plurality of holes with a metallic material, wherein the metallic material is in contact with the substrate; and
removing the resist layer.

14. An imaging device, comprising:
an array of nanowires formed on a substrate, wherein at least one nanowire in the array of nanowires includes a photoelectric element to produce a photocurrent based, at least in part, on incident photons absorbed by the at least one nanowire.

15. The imaging device of claim 14, wherein the at least one photoelectric element is a p-n junction.

16. The imaging device of claim 14, wherein at least two nanowires in the array have different radii to selectively absorb incident photons at a particular wavelength.

17. The imaging device of claim 14, further comprising at least one photodetector under the at least one nanowire, wherein the at least one nanowire absorbs photons at a first wavelength, but not a second wavelength and the photodetector absorbs photons at the second wavelength.

18. A method of fabricating an imaging device, the method comprising:
forming an epitaxial structure comprising an n-type semiconductor layer and a p-type semiconductor layer on a substrate to create a p-n junction between the n-type layer and the p-type layer;
etching the epitaxial structure to form an array of nanowires on the substrate, wherein each nanowire includes a p-n junction as formed in the epitaxial structure; and
forming an electrical contact on at least one nanowire in the array of nanowires.

19. The method of claim 17, further comprising:
forming a polymer layer on the substrate to at least partially planarize the surface of the array of nanowires.

20. The method of claim 17, wherein the polymer layer is polymethyl methacrylate.
forming a plurality of holes in the resist layer at a plurality of locations to expose the substrate;
filling, at least in partially, the plurality of holes with a metallic material, wherein the metallic material is in contact with the substrate; and
removing the resist layer.
